(19) United States
(12) Patent Application Publication
(10) Pub. No.: US 2024/0072107 A1
(43) Pub. Date: Feb. 29, 2024

(54) SEMICONDUCTOR DEVICE, MATCHING CIRCUIT, AND FILTER CIRCUIT

(71) Applicant: Murata Manufacturing Co., Ltd., Nagaokakyo-shi (JP)

(72) Inventors: Masatomi HARADA, Nagaokakyo-shi (JP); Korekiyo ITO, Nagaokakyo-shi (JP); Takeshi KAGAWA, Nagaokakyo-shi (JP)

(21) Appl. No.: 18/502,482

(22) Filed: Nov. 6, 2023

Related U.S. Application Data
(63) Continuation of application No. PCT/JP2022/019625, filed on May 9, 2022.

(30) Foreign Application Priority Data
May 10, 2021 (JP) 2021-079849

(51) Int. Cl. H01L 23/00; H03H 7/01; H03H 7/38

(52) U.S. Cl. CPC H01L 28/60; H01L 23/564; H03H 7/0115; H03H 7/38

(57) ABSTRACT

A semiconductor device that includes a substrate; a first electrode layer on the substrate; a dielectric film on the first electrode layer; a second electrode layer on the dielectric film; a protective layer covering the first electrode layer and the second electrode layer; and an outer electrode penetrating the protective layer. The dielectric film includes silicon nitride, and an atomic concentration ratio of Si to a total amount of Si and N contained in the dielectric film is 43 atom % to 70 atom %.

### CROSS REFERENCE TO RELATED APPLICATIONS

The present application is a continuation of International application No. PCT/JP2022/019625, filed May 9, 2022, which claims priority to Japanese Patent Application No. 2021-079849, filed May 10, 2021, the entire contents of each of which are incorporated herein by reference.

### TECHNICAL FIELD

The present invention relates to a semiconductor device. Moreover, the present invention relates to a matching circuit and a filter circuit provided with the semiconductor device.

### BACKGROUND ART

As a typical capacitor element used for a semiconductor integrated circuit, for example, a metal insulator metal (MIM) capacitor is known. The MIM capacitor is a capacitor having a parallel plate-shaped structure in which an insulator is sandwiched between a lower electrode and an upper electrode.

Patent Document 1 discloses a capacitor component including a lower electrode formed on a substrate, a dielectric thin film formed on the lower electrode, an upper electrode formed on the dielectric thin film, an insulating layer formed on the substrate and including the upper electrode, and a pair of electrode terminals connected to the respective electrodes and having end portions disposed to be located on the same plane.
Patent Document 1: Japanese Unexamined Patent Application Publication No. 5-47586

### SUMMARY OF THE INVENTION

Patent Document 1 states that, for example, silicon dioxide, tantalum pentoxide, strontium titanate, barium titanate, calcium titanate, and the like are used as material of the dielectric thin film.

When a semiconductor device such as the capacitor component (capacitor) described in Patent Document 1 is used as a capacitor for a matching circuit or the like, a high quality factor is required. However, a dielectric film suitable for increasing a quality factor of a semiconductor device has not sufficiently been examined.

The present invention is made in view of solving the above problem, and one object thereof is to provide a semiconductor device having high quality-factor characteristics. Moreover, another object of the present invention is to provide a matching circuit and a filter circuit provided with the semiconductor device described above.

A semiconductor device according to an aspect of the present invention includes: a substrate; a first electrode layer on the substrate; a dielectric film on the first electrode layer; a second electrode layer on the dielectric film; a protective layer covering the first electrode layer and the second electrode layer; and an outer electrode penetrating the protective layer. The dielectric film includes silicon nitride, and an atomic concentration ratio of Si to a total amount of Si and N contained in the dielectric film is 43 atom % to 70 atom %.

A matching circuit according to another aspect of the present invention includes the aforementioned semiconductor device.

A filter circuit according to a further aspect of the present invention includes the aforementioned semiconductor device.

According to aspects of the present invention, a semiconductor device having high quality-factor characteristics can be provided. Moreover, according to other aspects of the present invention, a matching circuit and a filter circuit provided with the semiconductor device described above can be provided.

### BRIEF DESCRIPTION OF THE DRAWINGS

FIG. 1 is a sectional view schematically illustrating one example of a capacitor according to a first embodiment of the present invention.

FIG. 2 is a plan view schematically illustrating one example of the capacitor according to the first embodiment of the present invention.

FIG. 3 is a graph illustrating a relation between an atomic concentration ratio of Si to a total amount of Si and N contained in a dielectric film and a quality factor at capacitance of 0.2 pF.

FIG. 4 is a graph illustrating a relation between a content of F contained in the dielectric film and the quality factor.

FIG. 5A is a schematic sectional view illustrating one example of a process of forming an insulating film.

FIG. 5B is a schematic sectional view illustrating one example of a process of forming a first electrode layer.

FIG. 5C is a schematic sectional view illustrating one example of a process of forming a dielectric film.

FIG. 5D is a schematic sectional view illustrating one example of a process of forming a second electrode layer.

FIG. 5E is a schematic sectional view illustrating one example of a process of forming a moisture-resistant film.

FIG. 5F is a schematic sectional view illustrating one example of a process of forming a protective layer.

FIG. 5G is a schematic sectional view illustrating one example of a process of forming a seed layer.

FIG. 5H is a schematic sectional view illustrating one example of a process of forming a first plating layer and a second plating layer.

FIG. 5I is a schematic sectional view illustrating one example of a process of removing a portion of the seed layer.

FIG. 5J is a schematic sectional view illustrating one example of a process of forming a photosensitive resin film.

FIG. 5K is a schematic sectional view illustrating one example of a process of forming a first resin body and a second resin body.

FIG. 6 is a sectional view schematically illustrating one example of a capacitor according to a second embodiment of the present invention.

FIG. 7 is an explanatory diagram illustrating one example of a matching circuit.

FIG. 8 is an explanatory diagram illustrating one example of a filter circuit.

### DETAILED DESCRIPTION OF THE PREFERRED EMBODIMENTS

Hereinafter, a semiconductor device according to preferred aspects of the present invention is described.

However, the present invention is not limited to the following configurations and can be appropriately modified and applied in a scope not changing the gist of the present invention. Note that the present invention also includes combination of two or more preferable configurations of the present invention which will be described below.

Needless to say, each embodiment described below is merely illustration, and partial replacement or combination of configurations described in different embodiments is possible. In a second embodiment and thereafter, description of matters in common with a first embodiment is omitted, and only a different point is described. Particularly, similar effects and operation as a result of similar configurations are not mentioned in each embodiment.

In the following description, when the respective embodiments are not particularly distinguished, a phrase of “semiconductor device of the present invention” is simply used. Shapes, arrangement, and the like of the semiconductor device and the respective components of the present invention are not limited by the examples illustrated in the drawings.

Moreover, as one embodiment of the semiconductor device of the present invention, a capacitor is described below as one example. The semiconductor device of the present invention may be a capacitor itself (that is, a capacitor element), or may be a device including a capacitor.

### First Embodiment

In a capacitor according to a first embodiment of the present invention, an outer electrode includes a first outer electrode connected to a first electrode layer, and a second outer electrode connected to a second electrode layer.

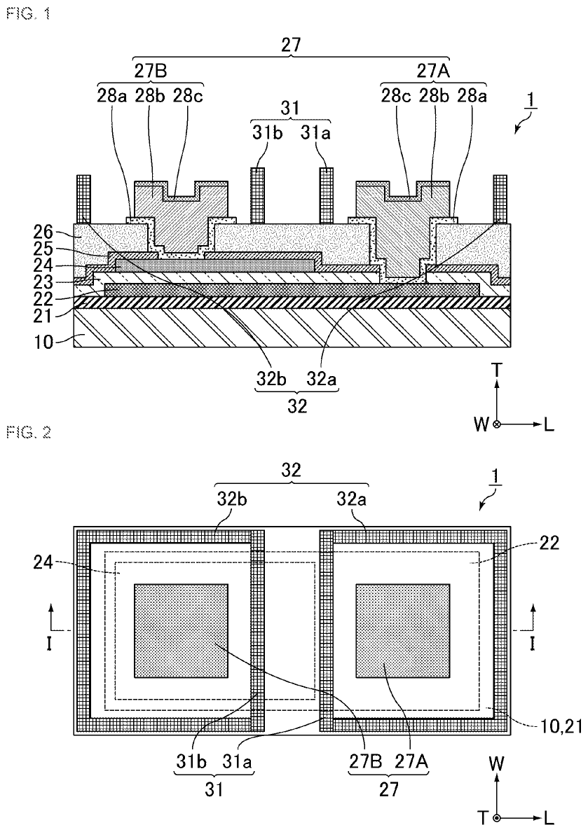

FIG. 1 is a sectional view schematically illustrating one example of the capacitor according to the first embodiment of the present invention. FIG. 2 is a plan view schematically illustrating one example of the capacitor according to the first embodiment of the present invention. FIG. 1 is a sectional view of the capacitor taken along an I-I line illustrated in FIG. 2.

Herein, a length direction, a width direction, and a thickness direction of the capacitor (semiconductor device) are directions respectively defined by an arrow L, an arrow W, and an arrow T as illustrated in FIG. 1, FIG. 2, and the like. Here, the length direction L, the width direction W, and the thickness direction T are orthogonal to each other.

A capacitor 1 illustrated in FIGS. 1 and 2 includes a substrate 10, an insulating film 21 provided on the substrate 10, a first electrode layer 22 provided on the insulating film 21, a dielectric film 23 provided on the first electrode layer 22, a second electrode layer 24 provided on the dielectric film 23, a moisture-resistant film 25 provided on the dielectric film 23 and the second electrode layer 24, a protective layer 26 provided on the moisture-resistant film 25, and an outer electrode 27 penetrating the protective layer 26. The outer electrode 27 includes a first outer electrode 27A connected to the first electrode layer 22, and a second outer electrode 27B connected to the second electrode layer 24. The first outer electrode 27A penetrates the protective layer 26, the moisture-resistant film 25, and the dielectric film 23, and the second outer electrode 27B penetrates the protective layer 26 and the moisture-resistant film 25.

Although the substrate 10 is not particularly limited, it is preferably a semiconductor substrate such as a silicon substrate and a gallium arsenide substrate, or an insulating substrate such as glass and alumina.

The insulating film 21 is provided to cover the entire one principal surface of the substrate 10. The insulating film 21 may be provided to cover a portion of the one principal surface of the substrate 10. However, the insulating film 21 needs to be larger than the first electrode layer 22, and be provided to a range overlapping with the entire area of the first electrode layer 22. Note that when the substrate 10 is an insulating substrate such as glass and alumina, the insulating film 21 is not necessarily provided.

Although material included in the insulating film 21 is not particularly limited, it is preferably SiO₂, SiN, Al₂O₃, HfO₂, Ta₂O₅, or ZrO₂, for example.

The first electrode layer 22 is provided at a position separate from an end portion of the substrate 10. That is, an end portion of the first electrode layer 22 is located at an inner side with respect to the end portion of the substrate 10.

Although material included in the first electrode layer 22 is not particularly limited, it is preferably Cu, Ag, Au, Al, Ni, Cr, or Ti, or alloy including at least one of these metals, for example.

The dielectric film 23 is provided such that its portion excluding an opening covers the first electrode layer 22. In FIG. 1, an end portion of the dielectric film 23 is also provided on a surface of the insulating film 21 located between the end portion of the first electrode layer 22 and the end portion of the substrate 10. The end portion of the dielectric film 23 is not necessarily provided to the end portion of the substrate 10.

The dielectric film 23 is made of silicon nitride. Specifically, an atomic concentration ratio of Si to a total amount of Si and N contained in the dielectric film 23 is 43 atom % to 70 atom %.

Although a thickness of the dielectric film 23 is not particularly limited, it is adjusted in accordance with a desired capacitance value. For example, when the dielectric film 23 is used at capacitance of 3 pF or smaller, the thickness of the dielectric film 23 is preferably 0.4 μm or larger, and is more preferably 0.44 μm or larger. On the other hand, the thickness of the dielectric film 23 is preferably 5 μm or smaller, and is more preferably 4 μm or smaller.

The second electrode layer 24 is provided to be opposed to the first electrode layer 22 while having the dielectric film 23 therebetween.

Although material included in the second electrode layer 24 is not particularly limited, it is preferably Cu, Ag, Au, Al, Ni, Cr, or Ti, or alloy including at least one of these metals, for example.

The moisture-resistant film 25 is provided such that its portion excluding an opening covers the dielectric film 23 and the second electrode layer 24. Since the moisture-resistant film 25 is provided, moisture resistance of the capacitor element, especially, the dielectric film 23 is increased. Note that the moisture-resistant film 25 is not necessarily provided.

Although material included in the moisture-resistant film 25 is not particularly limited, it is preferably moisture-resistant material such as SiO₂ and SiN.

The protective layer 26 has an opening at each of a position overlapping with the openings of the dielectric film 23 and the moisture-resistant film 25 (an opening overlapping with the first electrode layer 22), and a position overlapping with the opening of the moisture-resistant film 25 (an opening overlapping with the second electrode layer 24). Since the protective layer 26 is provided, the capacitor element, especially, the dielectric film 23 is protected from moisture.

Although material included in the protective layer 26 is not particularly limited, it is preferably resin material such as polyimide resin, and resin in solder resist.

Although material included in the outer electrode 27 is not particularly limited, it is preferably Cu, Ni, Ag, Au, or Al, for example. The outer electrode 27 may have a single-layer structure, or may have a multilayer structure. An outermost surface of the outer electrode 27 preferably includes Au or Sn.

When the first outer electrode 27A has a multilayer structure, as illustrated in FIG. 1, the first outer electrode 27A may include a seed layer 28a, a first plating layer 28b, and a second plating layer 28c in this order from the substrate 10 side.

The seed layer 28a of the first outer electrode 27A is, for example, a multilayer body (Ti/Cu) of a conductive layer including titanium (Ti) and a conductive layer including copper (Cu).

Constituent material of the first plating layer 28b of the first outer electrode 27A is, for example, nickel (Ni).

Constituent material of the second plating layer 28c of the first outer electrode 27A is, for example, gold (Au) or tin (Sn).

When the second outer electrode 27B has a multilayer structure, as illustrated in FIG. 1, the second outer electrode 27B may include the seed layer 28a, the first plating layer 28b, and the second plating layer 28c in this order from the substrate 10 side.

The seed layer 28a of the second outer electrode 27B is, for example, a multilayer body (Ti/Cu) of a conductive layer including titanium (Ti) and a conductive layer including copper (Cu).

Constituent material of the first plating layer 28b of the second outer electrode 27B is, for example, nickel (Ni).

Constituent material of the second plating layer 28c of the second outer electrode 27B is, for example, gold (Au) or tin (Sn).

The constituent material of the first outer electrode 27A and the constituent material of the second outer electrode 27B may be the same as or different from each other.

As illustrated in FIGS. 1 and 2, in plan view seen in the thickness direction T, a first resin body 31 may be provided between the first outer electrode 27A and the second outer electrode 27B. The first resin body 31 is provided, for example, to the surface of the protective layer 26.

As illustrated in FIG. 1, in the thickness direction T, a tip end of the first resin body 31 is preferably located at a position higher than tip ends of the first outer electrode 27A and the second outer electrode 27B. In this case, when the capacitor 1 is mounted on a wiring board, the first resin body 31 contacts the wiring board side (for example, an upper surface of the wiring board, a land, solder, and the like) before the first outer electrode 27A and the second outer electrode 27B contact the wiring board side. Therefore, load is applied to the first resin body 31, and load to be applied to the first outer electrode 27A and the second outer electrode 27B is suppressed. As a result, since it is suppressed that the load is transferred to the capacitor element through the first outer electrode 27A and the second outer electrode 27B, damage of the capacitor element, especially, damage of the dielectric film 23 is suppressed.

The first resin body 31 preferably includes at least one resin selected from the group consisting of resin in solder resist, polyimide resin, polyimide-amide resin, and epoxy resin. The first resin body 31 is preferably a solidified object of photosensitive resin.

The first resin body 31 may include a first wall portion 31a provided proximal to the first outer electrode 27A, and a second wall portion 31b provided proximal to the second outer electrode 27B and separated from the first wall portion 31a. In plan view as illustrated in FIG. 2, the first wall portion 31a and the second wall portion 31b are preferably provided in parallel to each other.

The first wall portion 31a may have an opening communicating to space which separates the first wall portion 31a and the second wall portion 31b. Similarly, the second wall portion 31b may have an opening communicating to space which separates the first wall portion 31a and the second wall portion 31b.

As illustrated in FIGS. 1 and 2, in plan view seen in the thickness direction T, a second resin body 32 may be provided between the end portion of the substrate 10 and the first outer electrode 27A, and between the end portion of the substrate 10 and the second outer electrode 27B. The second resin body 32 is provided, for example, to the surface of the protective layer 26. Moreover, the second resin body 32 may be provided to an outer side portion of the protective layer 26, and in this case, it may be provided on the substrate 10.

As illustrated in FIG. 1, in the thickness direction T, a tip end of the second resin body 32 is preferably located at a position higher than the tip ends of the first outer electrode 27A and the second outer electrode 27B. In this case, for example, when the capacitor 1 is mounted on the wiring board, load can more widely be spread by the second resin body 32. Therefore, load to be applied to the capacitor element, especially, to the dielectric film 23 can sufficiently be suppressed.

Moreover, as illustrated in FIG. 1, in the thickness direction T, the tip-end of the second resin body 32 is preferably located at a position lower than the tip end of the first resin body 31. In this case, for example, when the capacitor 1 is mounted on the wiring board, it can stably be held on the wiring board by the first resin body 31.

The second resin body 32 preferably includes at least one resin selected from the group consisting of resin in solder resist, polyimide resin, polyimide-amide resin, and epoxy resin. The second resin body 32 is preferably a solidified object of photosensitive resin.

Resin included in the first resin body 31 and resin included in the second resin body 32 may be the same as or different from each other.

As illustrated in FIG. 2, the second resin body 32 preferably includes a first peripheral portion 32a and a second peripheral portion 32b. In plan view seen in the thickness direction T, the first peripheral portion 32a is provided along the end portion of the substrate 10 between the end portion of the substrate 10 and the first outer electrode 27A. The second peripheral portion 32b is provided along the end portion of the substrate 10 between the end portion of the substrate 10 and the second outer electrode 27B.

The first wall portion 31a and the first peripheral portion 32a are preferably connected to each other. Moreover, the second wall portion 31b and the second peripheral portion 32b are preferably connected to each other.

In the semiconductor device of the present invention, the atomic concentration ratio of Si to the total amount of Si and N contained in the dielectric film is 43 atom % to 70 atom %.

FIG. 3 is a graph illustrating a relation between the atomic concentration ratio of Si to the total amount of Si and N contained in the dielectric film and a quality factor at capacitance of 0.2 pF.

In Si₃N₄ which is silicon nitride at a stoichiometric ratio, the atomic concentration ratio of Si to the total amount of Si and N (referred to as the ratio “Si/(Si+N)” in FIG. 3) is 42.8 atom %. Relative values when a quality factor at this time is normalized as 100% are illustrated in FIG. 3.

As illustrated in FIG. 3, it can be confirmed that when the atomic concentration ratio of Si to the total amount of Si and N contained in the dielectric film is 43 atom % or larger, the quality factor improves. On the other hand, when the atomic concentration ratio of Si to the total amount of Si and N contained in the dielectric film is smaller than 43 atom %, an improvement effect of the quality factor is small.

Moreover, when the atomic concentration ratio of Si to the total amount of Si and N contained in the dielectric film exceeds 70 atom %, current leakage increases, and thus the quality factor is considered to be lowered.

When the atomic concentration ratio of Si to the total amount of Si and N contained in the dielectric film exceeds 60 atom %, electrostatic breakdown voltage of the dielectric film is reduced. Therefore, it becomes difficult to satisfy human body model (HBM)-electrostatic discharge (ESD) pressure resistance which is required to an electronic component. Therefore, the atomic concentration ratio of Si to the total amount of Si and N contained in the dielectric film is preferably 60 atom % or smaller.

When the atomic concentration ratio of Si to the total amount of Si and N contained in the dielectric film is smaller than 50 atom %, the relative value of the quality factor falls below 125%, and thus an improvement effect is small. Therefore, the atomic concentration ratio of Si to the total amount of Si and N contained in the dielectric film is preferably 50 atom % or larger.

The atomic concentration ratio of Si to the total amount of Si and N contained in the dielectric film can be calculated thorough analysis of a constituent element of the dielectric film by X-ray photoelectron spectroscopy (XPS).

Measurement conditions of the XPS are described below.
Measurement device: Quantes (product of ULVAC-PHI, Inc.)
Measurement range: 100 μmφ
Measurement depth: 100 nm

In the semiconductor device of the present invention, a content of F contained in the dielectric film is preferably 10¹⁹ cm⁻³ or smaller.

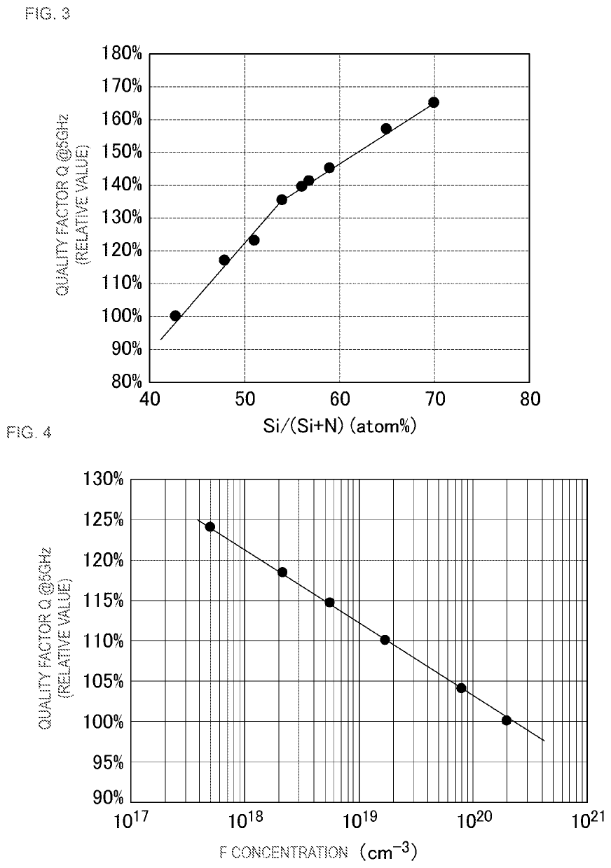

FIG. 4 is a graph illustrating a relation between the content of F contained in the dielectric film and the quality factor.

A content of F contained in the dielectric film including silicon nitride at the stoichiometric ratio (Si/(Si+N)=42.8 atom %) is 2×10²⁰ cm⁻³. Relative values when a quality factor at this time is normalized as 100% are illustrated in FIG. 4.

It was not known that the content of F contained in the dielectric film affects the quality factor. As illustrated in FIG. 4, it can be confirmed that when the content of F contained in the dielectric film is 10¹⁹ cm⁻³ or smaller, an increase rate of the quality factor becomes 10% or larger.

The content of F contained in the dielectric film can be measured by secondary-ion mass spectrometry (SIMS).
Measurement conditions of the SIMS are described below.
Measurement device: CAMECA IMS-6f
Primary ion species: Cs⁺
Primary accelerating voltage: 15 kV
Detection range: 8 μmφ

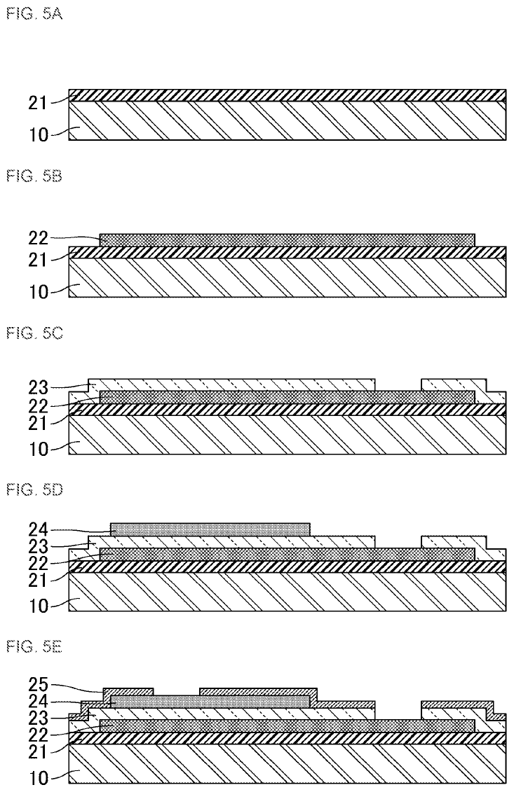

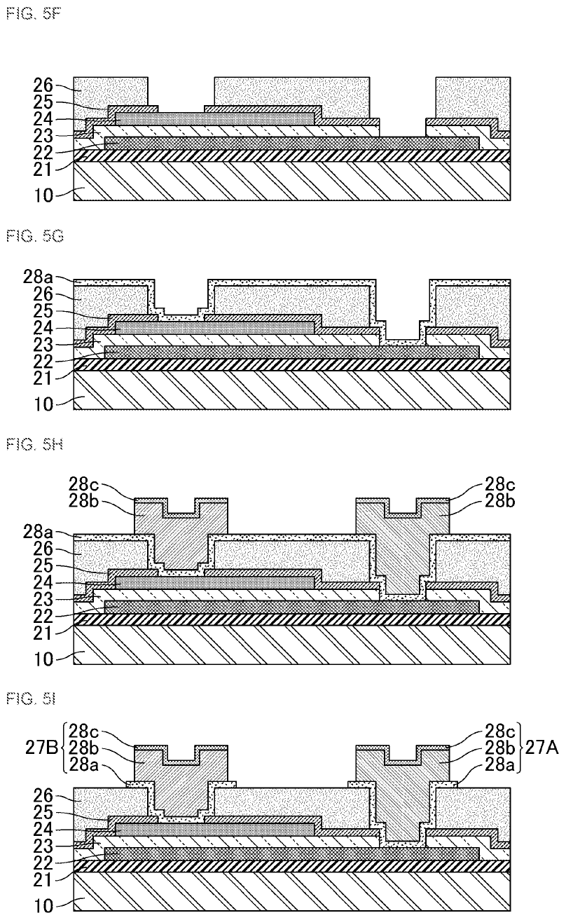

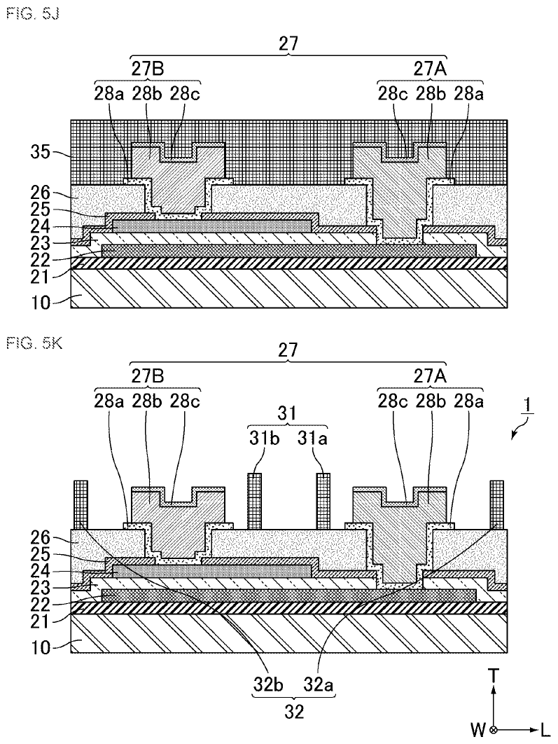

The capacitor 1 illustrated in FIG. 1 is manufactured in the following method, for example. FIGS. 5A to 5K are schematic sectional views illustrating one example of the manufacturing method of the capacitor according to the first embodiment of the present invention.

<Formation of Insulating Film>

FIG. 5A is a schematic sectional view illustrating one example of a process of forming an insulating film.

As illustrated in FIG. 5A, the insulating film 21 is formed on the substrate 10 by, for example, a thermal oxidation method, a sputtering method, or a chemical vapor deposition method.

<Formation of First Electrode Layer>

FIG. 5B is a schematic sectional view illustrating one example of a process of forming a first electrode layer.

A conductive layer including the constituent material of the first electrode layer 22 is formed on a surface of the insulating film 21 on the opposite side from the substrate 10 by, for example, a sputtering method. Then, patterning of the conductive layer is performed by combination of a photolithography method and an etching method, and thus the first electrode layer 22 as illustrated in FIG. 5B is formed. More specifically, the first electrode layer 22 is formed to be located to a position separate from the end portion of the substrate 10.

<Formation of Dielectric Film>

FIG. 5C is a schematic sectional view illustrating one example of a process of forming a dielectric film.

A layer including the constituent material of the dielectric film 23 is formed to cover the first electrode layer 22 by, for example, a sputtering method or a chemical vapor deposition method. Then, patterning of this layer is performed by, for example, combination of a photolithography method and an etching method, and thus the dielectric film 23 as illustrated in FIG. 5C is formed. More specifically, the dielectric film 23 is formed such that the opening which exposes a portion of the first electrode layer 22 is provided.

<Formation of Second Electrode Layer>

FIG. 5D is a schematic sectional view illustrating one example of a process of forming a second electrode layer.

A conductive layer including the constituent material of the second electrode layer 24 is formed on a surface of the structure body illustrated in FIG. 5C on the opposite side from the substrate 10 by, for example, a sputtering method. Then, patterning of the conductive layer is performed by, for example, combination of a photolithography method and an etching method, and thus the second electrode layer 24 as illustrated in FIG. 5D is formed. More specifically, the second electrode layer 24 is formed to be opposed to the first electrode layer 22 having the dielectric film 23 therebetween.

<Formation of Moisture-resistant Film>

FIG. 5E is a schematic sectional view illustrating one example of a process of forming a moisture-resistant film.

A layer including the constituent material of the moisture-resistant film 25 is formed on a surface of the structure body illustrated in FIG. 5D on the opposite side from the substrate 10 by, for example, a chemical vapor deposition method. Then, patterning of this layer is performed by, for example, combination of a photolithography method and an etching method, and thus the moisture-resistant film 25 as illustrated in FIG. 5E is formed. More specifically, the moisture-resistant film 25 is formed such that an opening is provided to each of the position overlapping with the opening of the dielectric film 23 which exposes a portion of the first electrode layer 22, and the position where a portion of the second electrode layer 24 is exposed.

<Formation of Protective Layer>

FIG. 5F is a schematic sectional view illustrating one example of a process of forming a protective layer.

A layer including the constituent material of the protective layer 26 is formed on a surface of the structure body illustrated in FIG. 5E on the opposite side from the substrate 10 by, for example, a spin coating method. Then, patterning of this layer is performed only using, for example, a photolithography method when the constituent material of the protective layer 26 is photosensitive, and by combination of a photolithography method and an etching method when the constituent material of the protective layer 26 is nonphotosensitive, and thus the protective layer 26 as illustrated in FIG. 5F is formed. More specifically, the protective layer 26 is formed such that an opening is provided to each of the position overlapping with the openings of the dielectric film 23 and the moisture-resistant film 25 which expose the portion of the first electrode layer 22, and a position overlapping with the opening of the moisture-resistant film 25 which exposes the portion of the second electrode layer 24.

<Formation of Outer Electrode>

FIG. 5G is a schematic sectional view illustrating one example of a process of forming a seed layer. FIG. 5H is a schematic sectional view illustrating one example of a process of forming a first plating layer and a second plating layer. FIG. 5I is a schematic sectional view illustrating one example of a process of removing a portion of the seed layer.

As illustrated in FIG. 5G, the seed layer 28a is formed on a surface of the structure body illustrated in FIG. 5F on the opposite side from the substrate 10. By combination of plating processing and a photolithography method, the first plating layer 28b and the second plating layer 28c as illustrated in FIG. 5H are sequentially formed. Then, as illustrated in FIG. 5I, a portion of the seed layer 28a is removed by, for example, an etching method. In the manner described above, as the outer electrode 27, the first outer electrode 27A and the second outer electrode 27B as illustrated in FIG. 5I are formed. More specifically, the first outer electrode 27A is formed to be connected to the first electrode layer 22 through the openings provided to the dielectric film 23, the moisture-resistant film 25, and the protective layer 26. Moreover, the second outer electrode 27B is formed to be connected to the second electrode layer 24 through the openings provided to the moisture-resistant film 25 and the protective layer 26.

<Formation of First Resin Body and Second Resin Body>

FIG. 5J is a schematic sectional view illustrating one example of a process of forming a photosensitive resin film. FIG. 5K is a schematic sectional view illustrating one example of a process of forming a first resin body and a second resin body.

As illustrated in FIG. 5J, a photosensitive resin film 35 is formed to cover the protective layer 26 and the outer electrode 27. Then, patterning of the photosensitive resin film 35 is performed by a photolithography method, and thus the first resin body 31 and the second resin body 32 as illustrated in FIG. 5K are formed.

In the manner described above, the capacitor 1 illustrated in FIG. 1 is manufactured.

Although the case in which one capacitor element is manufactured is described above, a plurality of capacitor elements may be manufactured at the same time by the plurality of capacitor elements being formed on a single substrate 10, and then the substrate 10 being cut and separated with a dicing machine or the like.

### Second Embodiment

A capacitor according to a second embodiment of the present invention further includes a third electrode layer provided on the dielectric film to be separate from the second electrode layer, and the outer electrode includes a first outer electrode connected to the third electrode layer, and the second outer electrode connected to the second electrode layer.

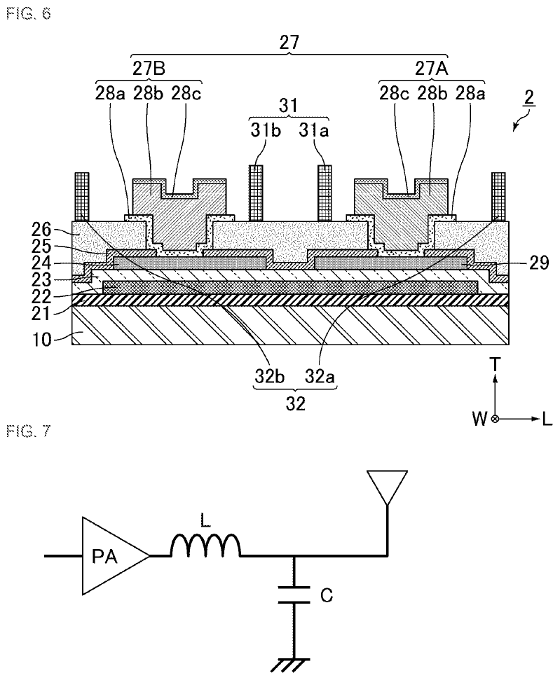

FIG. 6 is a sectional view schematically illustrating one example of the capacitor according to the second embodiment of the present invention.

A capacitor 2 illustrated in FIG. 6 includes the substrate 10, the insulating film 21 provided on the substrate 10, the first electrode layer 22 provided on the insulating film 21, the dielectric film 23 provided on the first electrode layer 22, the second electrode layer 24 provided on the dielectric film 23, a third electrode layer 29 provided on the dielectric film 23 while being separate from the second electrode layer 24, the moisture-resistant film 25 provided on the dielectric film 23, the second electrode layer 24, and the third electrode layer 29, the protective layer 26 provided on the moisture-resistant film 25, and the outer electrode 27 penetrating the protective layer 26. The outer electrode 27 includes the second outer electrode 27B connected to the second electrode layer 24, and the first outer electrode 27A connected to the third electrode layer 29. The first outer electrode 27A penetrates the protective layer 26 and the moisture-resistant film 25, and the second outer electrode 27B penetrates the protective layer 26 and the moisture-resistant film 25.

In the configuration of the capacitor 1 illustrated in FIG. 1, the capacitor is formed on the left side. However, in the configuration of the capacitor 2 illustrated in FIG. 6, the capacitors are formed on the left and right sides. In the configuration illustrated in FIG. 6, the portion where the first outer electrode 27A is connected to the first electrode layer 22 in the configuration illustrated in FIG. 1 is only replaced by the structure in which the first electrode layer 22, the dielectric film 23, and the third electrode layer 29 are provided in this order. Therefore, the configuration illustrated in FIG. 6 does not require space for forming an additional element to the configuration illustrated in FIG. 1. Thus, a capacitor with low capacitance can be made while having the same element area. Such a structure is effective when a dielectric film with a certain thickness or larger cannot be formed.

### Other Embodiments

The semiconductor device according to aspects of the present invention is not limited to the embodiments described above, but various application and modifications may be added within the scope of the present invention, in terms of the configurations and manufacturing conditions of the semiconductor device such as the capacitor.

The semiconductor device according to aspects of the present invention has high quality-factor characteristics, and thus the semiconductor device is suitably used as a capacitor of a matching circuit or a filter circuit. Aspects of the present invention also include the matching circuit or the filter circuit including the semiconductor device.

FIG. 7 is an explanatory diagram illustrating one example of the matching circuit.

For example, by the semiconductor device described herein being used for a capacitor C of the matching circuit illustrated in FIG. 7, power consumption of the entire circuit can be suppressed. For example, assuming that power consumption in the case of the atomic concentration ratio of Si to the total amount of Si and N contained in the dielectric film being 42.8 atom % (stoichiometric ratio) is 100%, power consumption in the case of the atomic concentration ratio of Si to the total amount of Si and N contained in the dielectric film being 55 atom % is suppressed to 89%.

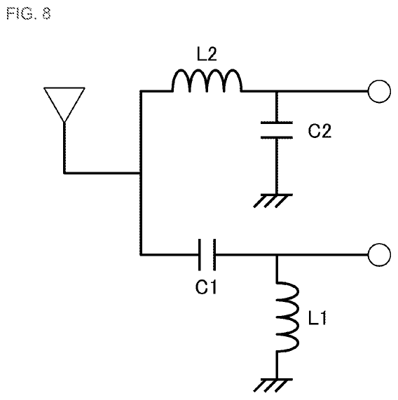

FIG. 8 is an explanatory diagram illustrating one example of the filter circuit.

For example, by the semiconductor device described herein being used for a capacitor C1 of the filter circuit illustrated in FIG. 8, power consumption of the entire circuit can be suppressed. For example, assuming that power consumption in the case of the atomic concentration ratio of Si to the total amount of Si and N contained in the dielectric film being 42.8 atom % (stoichiometric ratio) is 100%, power consumption in the case of the atomic concentration ratio of Si to the total amount of Si and N contained in the dielectric film being 55 atom % is suppressed to 95%.

### REFERENCE SIGNS LIST

1, 2 capacitor (semiconductor device)
10 substrate
21 insulating film
22 first electrode layer
23 dielectric film
24 second electrode layer
25 moisture-resistant film
26 protective layer
27 outer electrode
27A first outer electrode
27B second outer electrode
28a seed layer
28b first plating layer
28c second plating layer
29 third electrode layer
31 first resin body
31a first wall portion
31b second wall portion
32 second resin body
32a first peripheral portion
32b second peripheral portion
35 photosensitive resin film

1. A semiconductor device comprising:
a substrate;
a first electrode layer on the substrate;
a dielectric film on the first electrode layer;
a second electrode layer on the dielectric film;
a protective layer covering the first electrode layer and the second electrode layer; and
an outer electrode penetrating the protective layer, wherein
the dielectric film includes silicon nitride, and
an atomic concentration ratio of Si to a total amount of Si and N contained in the dielectric film is 43 atom % to 70 atom %.

2. The semiconductor device according to claim 1, further comprising an insulating film between the substrate and the first electrode layer.

3. The semiconductor device according to claim 2, further comprising a moisture-resistant film on the dielectric film and the second electrode layer, and between the protective layer and the first electrode layer and the second electrode layer.

4. The semiconductor device according to claim 1, further comprising a moisture-resistant film on the dielectric film and the second electrode layer, and between the protective layer and the first electrode layer and the second electrode layer.

5. The semiconductor device according to claim 1, wherein a content of F contained in the dielectric film is 10¹⁹ cm⁻³ or smaller.

6. The semiconductor device according to claim 1, wherein the outer electrode is a first outer electrode connected to the first electrode layer, and the semiconductor device further comprises a second outer electrode connected to the second electrode layer.

7. The semiconductor device according to claim 6, further comprising, in a plan view in a thickness direction, a first resin body between the first outer electrode and the second outer electrode.

8. The semiconductor device according to claim 7, wherein, in the thickness direction, a tip end of the first resin body is located at a position higher than tip ends of the first outer electrode and the second outer electrode.

9. The semiconductor device according to claim 7, wherein the first resin body includes a first wall portion proximal to the first outer electrode, and a second wall portion proximal to the second outer electrode and separated from the first wall portion.

10. The semiconductor device according to claim 9, wherein, in the plan view in the thickness direction, the first wall portion and the second wall portion are parallel to each other.

11. The semiconductor device according to claim 7, further comprising, in the plan view in the thickness direction, a second resin body between an end portion of the substrate and the first outer electrode, and between the end portion of the substrate and the second outer electrode.

12. The semiconductor device according to claim 11, wherein, in the thickness direction, a tip end of the second resin body is located at a position higher than tip ends of the first outer electrode and the second outer electrode.

13. The semiconductor device according to claim 12, wherein, in the thickness direction, the tip end of the second resin body is located at a position lower than the tip end of the first resin body.

14. The semiconductor device according to claim 11, wherein
the first resin body includes a first wall portion proximal to the first outer electrode, and a second wall portion proximal to the second outer electrode and separated from the first wall portion, and
the second resin body includes, in the plan view in the thickness direction, a first peripheral portion along the end portion of the substrate and between the end portion of the substrate and the first outer electrode, and a second peripheral portion along the end portion of the substrate and between the end portion of the substrate and the second outer electrode.

15. The semiconductor device according to claim 14, wherein the first wall portion and the first peripheral portion are connected to each other, and the second wall portion and the second peripheral portion are connected to each other.

16. The semiconductor device according to claim 1, further comprising:
a third electrode layer on the dielectric film and separate from the second electrode layer, wherein
the outer electrode is a first outer electrode connected to the third electrode layer, and the semiconductor device further comprises a second outer electrode connected to the second electrode layer.

17. A matching circuit comprising:
the semiconductor device according to claim 1.

18. A filter circuit comprising:
the conductor device according to claim 1.
